(19) United States
(12) Patent Application Publication
(10) Pub. No.: US 2026/0304734 A1
(43) Pub. Date: Oct. 1, 2026

(54) SEMICONDUCTOR DEVICE INCLUDING GATE ELECTRODES AND ACTIVE PATTERNS

(71) Applicant: Samsung Electronics Co., Ltd., Suwon-si (KR)

(72) Inventors: Hyunjin Lee, Suwon-si (KR); Minju Kang, Suwon-si (KR); Sujin Kang, Suwon-si (KR); Yongkwan Kim, Suwon-si (KR); Huijung Kim, Suwon-si (KR)

(73) Assignee: Samsung Electronics Co., Ltd., Suwon-si (KR)

(21) Appl. No.: 19/568,060

(22) Filed: Mar. 16, 2026

(30) Foreign Application Priority Data
Mar. 25, 2025 (KR) 10-2025-0037917

(51) Int. Cl. H10B 12/00

(52) U.S. Cl. CPC H10B 12/00

(57) ABSTRACT

A semiconductor device includes a first active pattern extending in a first horizontal direction, a first gate electrode at least partially overlapping the first active pattern in a vertical direction, a second active pattern including a first surface and a second surface, spaced apart from the first surface in the first horizontal direction, a bit line contacting the first surface of the second active pattern and extending in the vertical direction, a charge storage element contacting the second surface of the second active pattern, and a second gate electrode at least partially overlapping the second active pattern in the vertical direction. The first gate electrode and the second gate electrode are spaced apart from one another in the vertical direction, with the first active pattern and the second active pattern interposed therebetween.

### CROSS-REFERENCE TO RELATED APPLICATIONS

This present application claims priority to and the benefit under 35 U.S.C. § 119(a)-(d) of Korean Patent Application No. 10-2025-0037917, filed on Mar. 25, 2025, in the Korean Intellectual Property Office, the entire disclosure of which is incorporated herein by reference.

### FIELD

The present disclosed concepts relate to a semiconductor device and more particularly to a semiconductor device including gate electrodes and active patterns.

### BACKGROUND

As demand for high performance, high speed, and/or multifunctionality of semiconductor devices increases, a degree of integration of semiconductor devices is increasing. In manufacturing a semiconductor device with a fine pattern corresponding to the trend for a high degree of integration of semiconductor devices, it is required to implement patterns having a fine width or a fine separation distance.

### SUMMARY

According to example embodiments, a semiconductor device includes a first active pattern extending on a substrate in a first horizontal direction; a first gate electrode at least partially overlapping the first active pattern in a vertical direction and adjacent to the first active pattern; a second active pattern extending in the first horizontal direction, wherein the second active pattern includes a first surface and a second surface, spaced apart from the first surface in the first horizontal direction; a bit line contacting the first surface of the second active pattern and extending in the vertical direction; a charge storage element contacting the second surface of the second active pattern; and a second gate electrode at least partially overlapping the second active pattern in the vertical direction and adjacent to the second active pattern. The first gate electrode and the second gate electrode may be spaced apart from one another in the vertical direction, with the first active pattern and the second active pattern interposed therebetween.

According to example embodiments, a semiconductor device includes bit lines extending on a substrate in a first horizontal direction and a vertical direction, wherein the bit lines are spaced apart from one another in a second horizontal direction, intersecting the first horizontal direction; plate electrodes extending in the vertical direction and spaced apart from one another in the second horizontal direction, wherein the plate electrodes are spaced apart from the bit lines in the first horizontal direction; channel structures disposed between the bit lines and the plate electrodes and extending in the first horizontal direction, wherein the channel structures are spaced apart from one another in the first horizontal direction and the vertical direction, with the bit lines interposed therebetween; and first gate electrodes and second gate electrodes, spaced apart from one another in the vertical direction, with the channel structures interposed therebetween. The channel structures may include first active patterns extending in the first horizontal direction and adjacent to the first gate electrodes; second active patterns extending in the first horizontal direction and adjacent to the second gate electrodes; and charge storage elements contacting the second active patterns and disposed between the plate electrodes and the second active patterns.

According to example embodiments, a semiconductor device includes a first active pattern extending on a substrate in a first horizontal direction; a first gate electrode at least partially overlapping the first active pattern in a vertical direction and adjacent to the first active pattern, wherein the first gate electrode extends in a second horizontal direction, intersecting the first horizontal direction; a second active pattern extending in the first horizontal direction, wherein the second active pattern includes a first surface and a second surface, spaced apart from the first surface in the first horizontal direction; a bit line contacting the first surface of the second active pattern and extending in the vertical direction; a charge storage element contacting the second surface of the second active pattern; a second gate electrode at least partially overlapping the second active pattern in the vertical direction and adjacent to the second active pattern, wherein the second gate electrode extends in the second horizontal direction; a first gate capping layer and a second gate capping layer contacting the bit line and respectively contacting the first gate electrode and the second gate electrode; and a plate electrode spaced apart from the bit line in the first horizontal direction and contacting the first active pattern. The first gate electrode and the second gate electrode may be spaced apart from one another in the vertical direction, with the first active pattern and the second active pattern interposed therebetween. The second active pattern and the charge storage element may overlap the first active pattern in the vertical direction.

### BRIEF DESCRIPTION OF DRAWINGS

The above and other aspects, features, and advantages of the present disclosed concepts will be more clearly understood from the following detailed description, taken in conjunction with the accompanying drawings, in which:

FIG. 1 is a conceptual circuit diagram of a memory cell of a semiconductor device according to example embodiments.

FIG. 2 is a plan view of a semiconductor device according to example embodiments.

FIG. 3 is a schematic perspective view of a semiconductor device according to example embodiments.

FIG. 4 illustrates vertical cross-sectional views taken along lines I-I′ and II-II′ of the semiconductor device illustrated in FIG. 2.

FIG. 5 is an enlarged view of a portion of the semiconductor device illustrated in FIG. 4.

FIGS. 6 and 7 are vertical cross-sectional views of semiconductor devices according to example embodiments.

FIG. 8 illustrates I-V curves of active patterns according to the presence or absence of charge storage elements.

FIGS. 9 to 13 are vertical cross-sectional views of semiconductor devices according to example embodiments.

FIG. 14 is a flow chart illustrating a method for manufacturing a semiconductor device according to example embodiments.

FIGS. 15A to 25C are plan views, perspective views, and vertical cross-sectional views according to a process sequence to illustrate a method for manufacturing a semiconductor device according to example embodiments.

### DETAILED DESCRIPTION

Hereinafter, embodiments will be described with reference to the attached drawings.

One of the technical problems to be solved by the technical idea of the present disclosed concepts may be to provide a semiconductor device including gate electrodes extending in a horizontal direction and a bit line extending in a vertical direction.

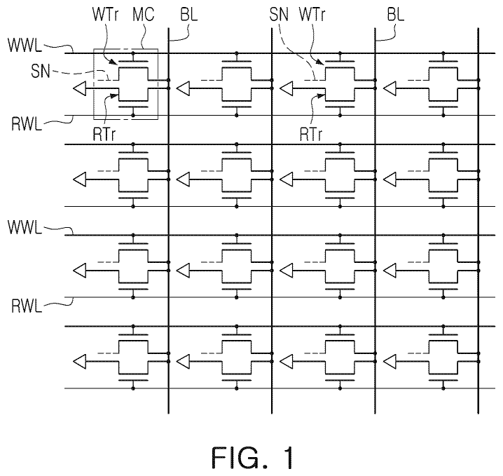

FIG. 1 is a conceptual circuit diagram of a memory cell of a semiconductor device according to example embodiments.

Referring to FIG. 1, memory cells MC may be connected to bit lines BL and word lines WWL and RWL. Each of the memory cells MC may include a write transistor Wtr, a read transistor Rtr, and a storage node SN. Charges may be stored in the storage node SN. The storage node SN may function as a gate (e.g., a floating gate) of the read transistor Rtr or may control a threshold voltage of the read transistor Rtr, and may be electrically connected to the write transistor Wtr. For example, the storage node SN may be electrically connected to a channel of the write transistor Wtr.

Each of the memory cells MC may be selected by the bit lines BL and the word lines WWL and RWL. Each of the memory cells MC may operate as a DRAM memory cell in which a write operation for storing information and a read operation for reading information may be performed, and may not include a capacitor. For example, each of the memory cells MC may store information in the storage node SN instead of the capacitor, and may be referred to as a 2T memory cell.

The write transistor Wtr may store charges in the storage node SN. Depending on amounts of the charges stored in the storage node SN, a threshold voltage of the read transistor Rtr in which the storage node SN functions as a gate may be changed. Depending on the threshold voltage of the read transistor Rtr, information stored in the memory cell may be read as ‘0’ or ‘1.’

One end of the channel of the write transistor Wtr may be connected to the bit line BL, and the other end may be connected to the storage node SN. A gate of the write transistor Wtr may be electrically connected to the write word line WWL.

One end of the channel of the read transistor Rtr may be connected to the bit line BL, and the other end may be grounded. The gate of the read transistor Rtr may be electrically connected to the read word line RWL. The storage node SN and the read word line RWL may be used for an on/off operation of the read transistor Rtr.

A bit line BL may be electrically connected to a memory cell MC. For example, the bit line BL may be electrically connected to a channel of the write transistor Wtr and a channel of the read transistor Rtr. In FIG. 1, the write word line WWL and the read word line RWL are illustrated as separate interconnections, but may not be limited thereto. In embodiments, the write word line WWL may be electrically connected to the read word line RWL, and may function as a single interconnection.

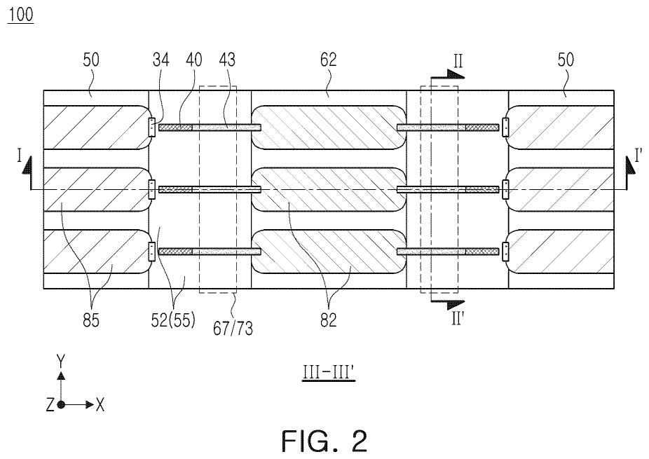

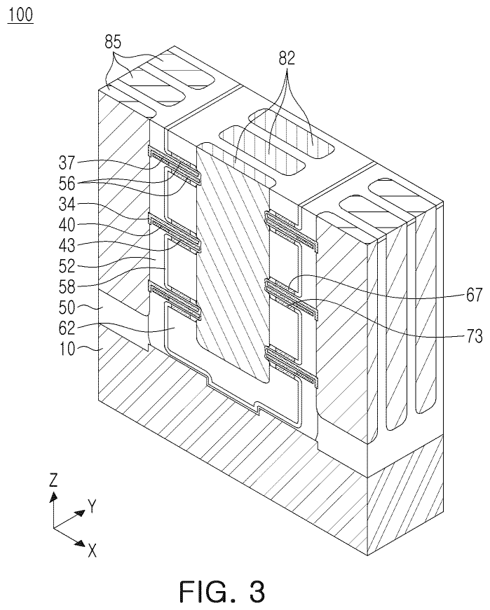

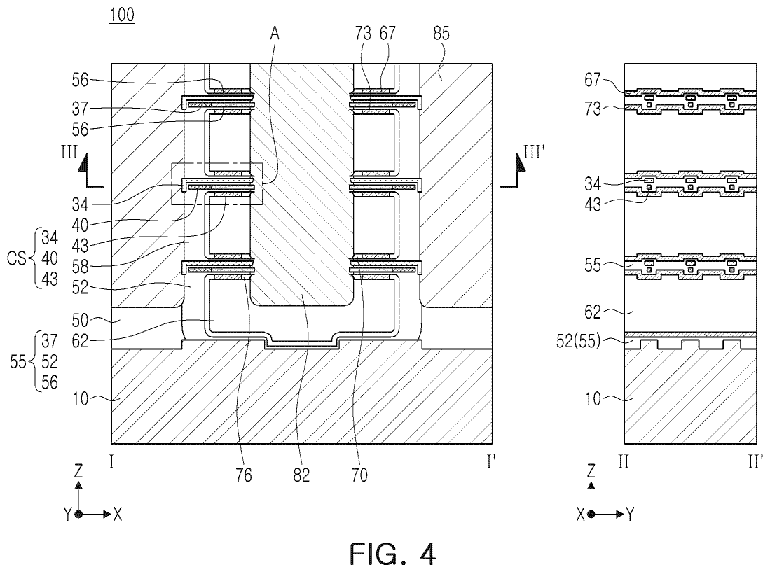

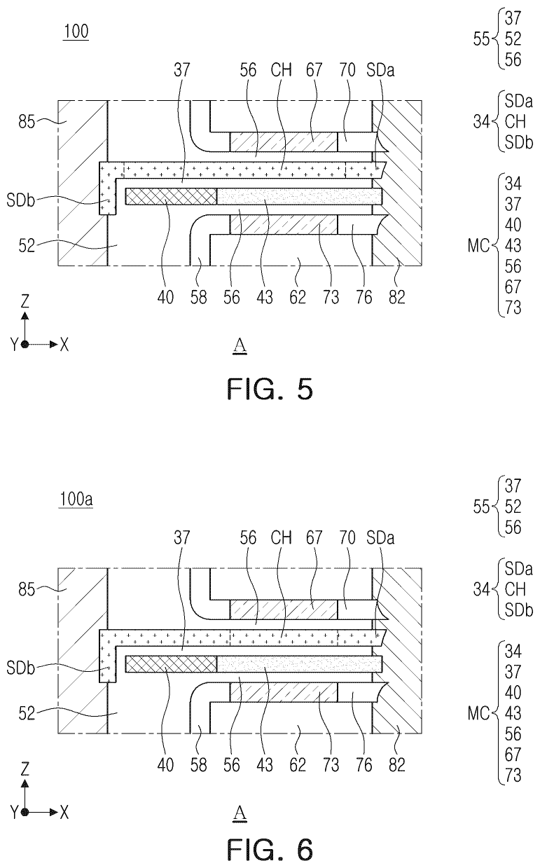

FIG. 2 is a plan view of a semiconductor device according to example embodiments. FIG. 3 is a schematic perspective view of a semiconductor device according to example embodiments. FIG. 4 illustrates vertical cross-sectional views taken along lines I-I′ and II-II′ of the semiconductor device illustrated in FIG. 2. FIG. 2 may correspond to a vertical cross-sectional view along line III-III′ of the semiconductor device illustrated in FIG. 4. FIG. 5 is an enlarged view of a portion of the semiconductor device illustrated in FIG. 4. FIG. 5 may correspond to region A of FIG. 4.

Referring to FIGS. 2 to 5, a semiconductor device 100 according to embodiments may include a substrate 10, a first active pattern 34, a charge storage element 40, a second active pattern 43, a dielectric structure 55, a first gate electrode 67, a second gate electrode 73, a bit line 82, and a plate electrode 85.

The read transistor Rtr described with reference to FIG. 1 may include the first active pattern 34. The first gate electrode 67 may correspond to a read word line RWL. The charge storage element 40 may be electrically connected to the first active pattern 34, and may include the storage node SN described with reference to FIG. 1. The charge storage element 40 may also function as a gate of the read transistor Rtr. A portion of the dielectric structure 55 between the first active pattern 34 and the first gate electrode 67 may be included in the read transistor Rtr.

The write transistor Wtr described with reference to FIG. 1 may include the second active pattern 43. The second gate electrode 73 may correspond to a write word line WWL. A portion in which the second gate electrode 73 overlaps the second active pattern 43 in the vertical direction (Z-direction) may function as a gate of the write transistor Wtr. A portion of the dielectric structure 55 between the second active pattern 43 and the second gate electrode 73 may be included in the write transistor Wtr.

The bit line 82 may be electrically connected to the first active pattern 34 and the second active pattern 43. The bit line 82 may include the bit line BL described with reference to FIG. 1.

The substrate 10 may include a semiconductor material, such as a group IV semiconductor, a group III-V compound semiconductor, or a group II-VI compound semiconductor. For example, the group IV semiconductor may include silicon, germanium, or silicon-germanium.

The first active patterns 34 may extend in an X-direction, and may be spaced apart from one another in the X-direction, a Y-direction, and the vertical direction. According to embodiments, the first active patterns 34 may include at least one of a polycrystalline semiconductor material, an oxide semiconductor material such as indium gallium zinc oxide (IGZO) or the like, or a two-dimensional material such as MoS₂ or the like.

In embodiments, each of the first active patterns 34 may include a single-crystal semiconductor material such as single-crystal silicon, and may include a first source/drain region SDa, a second source/drain region SDb, and a channel region CH, as illustrated in FIG. 5. The first source/drain region SDa may be in contact with the bit line 82, and the second source/drain region SDb may be in contact with the plate electrode 85. The channel region CH may be disposed between the first source/drain region SDa and the second source/drain region SDb in the X-direction.

The first source/drain region SDa and the second source/drain region SDb may include impurities. In embodiments, when the read transistor Rtr is an NMOS transistor, the first source/drain region SDa and the second source/drain region SDb may include an N-type impurity, such as P, As, or the like. In embodiments, when the read transistor Rtr is a PMOS transistor, the first source/drain region SDa and the second source/drain region SDb may include a P-type impurity, such as B or Al.

In embodiments, each of the first active patterns 34 may have a folded shape, and may have, for example, an L-shape. Each of the first active patterns 34 may include a first portion extending in the vertical direction, and a second portion extending in the X-direction from an end portion of the first portion. The first portion may be in contact with the plate electrode 85.

In embodiments, each of the first active patterns 34 may include an oxide semiconductor material. The oxide semiconductor material may be indium gallium zinc oxide (IGZO). However, embodiments is not limited thereto. For example, the oxide semiconductor material may include at least one of indium tungsten oxide (IWO), indium tin gallium oxide (ITGO), indium aluminum zinc oxide (IAZO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxynitride (ZnON), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), or indium gallium silicon oxide (InGaSiO).

The two-dimensional material may include at least one of a transition metal dichalcogenide (TMD) material layer, a black phosphorous material layer, or a hexagonal boron-nitride (hBN) material layer, having semiconductor properties. For example, the two-dimensional material may include at least one of BiOSe, Crl, WSe₂, MoS₂, TaS, WS, SnSe, ReS, β-SnTe, MnO, AsS, P(black), InSe, h-BN, GaSe, GaN, SrTiO, MXene, or an Janus 2D material, which may form a two-dimensional material.

When the first active patterns 34 include an oxide semiconductor material, the first active patterns 34 may not include the first source/drain region SDa and the second source/drain region SDb, described above.

The second active patterns 43 may extend in the X-direction, and may be spaced apart from one another in the X-direction, the Y-direction, and the vertical direction. The second active patterns 43 may be disposed to be adjacent to the first active patterns 34, and may overlap the first active patterns 34 in the vertical direction. For example, the second portions extending in the X-direction of each of the first active patterns 34 may overlap the second active patterns 43 in the vertical direction. A horizontal length of each of the second active patterns 43 in the X-direction may be smaller than a horizontal length of each of the first active patterns 34 in the X-direction.

According to embodiments, the second active patterns 43 may include at least one of a single-crystal semiconductor material such as single-crystal silicon, a polycrystalline semiconductor material, an oxide semiconductor material such as indium gallium zinc oxide (IGZO) or the like, or a two-dimensional material such as MoS₂ or the like.

The charge storage elements 40 may extend in the X-direction, and may be spaced apart from one another in the X-direction, the Y-direction, and the vertical direction. The charge storage elements 40 may be in contact with the second active patterns 43. For example, each of the second active patterns 43 may include a first surface and a second surface, perpendicular to the Y-direction. The first surface may be in contact with the bit line 82, and the second surface may be opposite to the first surface, and may be in contact with the charge storage element 40. The charge storage elements 40 may be disposed to be adjacent to the first active patterns 34, and may overlap the first active patterns 34 in the vertical direction. For example, the second portions of each of the first active patterns 34 extending in the X-direction may overlap the charge storage elements 40 in the vertical direction. The charge storage elements 40 may be disposed between the first portions extending in the vertical direction of each of the first active patterns 34, and the second active patterns 43.

In embodiments, the charge storage elements 40 may overlap the channel regions CH of the first active patterns 34 in the vertical direction. Depending on whether charges are stored in the charge storage elements 40, a threshold voltage of the first active patterns 34 may be adjusted, and channel resistance may be adjusted.

The charge storage elements 40 may include a conductive material, for example, doped single crystal silicon, doped polycrystalline silicon, a metal, a conductive metal nitride, a metal-semiconductor compound, a conductive metal oxide, conductive graphene, carbon nanotubes, or a combination thereof. In embodiments, the charge storage elements 40 may include an oxide semiconductor, such as IGZO.

The first active pattern 34, the charge storage element 40, and the second active pattern 43 may form a channel structure CS. Channel structures CS may extend in the X-direction, and may be spaced apart from one another in the X-direction, the Y-direction, and the vertical direction.

The first gate electrodes 67 may extend in the Y-direction, and may be spaced apart from one another in the X-direction and the vertical direction. The first gate electrodes 67 may be disposed to be adjacent to the first active patterns 34. For example, the first gate electrodes 67 may at least partially overlap the first active patterns 34 in the vertical direction. In embodiments, the first gate electrodes 67 may overlap the channel regions CH of the first active patterns 34 in the vertical direction. A horizontal length of the first gate electrodes 67 in the X-direction may be smaller than a horizontal length of the first active patterns 34 in the X-direction.

The second gate electrodes 73 may extend in the Y-direction, and may be spaced apart from one another in the X-direction and the vertical direction. The second gate electrodes 73 may be spaced apart from the first gate electrodes 67 in the vertical direction, with the channel structures CS interposed therebetween. The second gate electrodes 73 may be disposed to be adjacent to the second active patterns 43. For example, the second gate electrodes 73 may at least partially overlap the second active patterns 43 in the vertical direction. In embodiments, the second gate electrodes 73 may overlap the channel regions CH of the second active patterns 43 in the vertical direction. A horizontal length of the second gate electrodes 73 in the X-direction may be smaller than a horizontal length of the second active patterns 43 in the X-direction.

The first gate electrodes 67 and the second gate electrodes 73 may include doped polysilicon, a metal, a conductive metal nitride, a metal-semiconductor compound, a metal compound, a conductive metal oxide, graphene, carbon nanotubes, or a combination thereof. For example, at least one of the first gate electrodes 67 or the second gate electrodes 73 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes, or a combination thereof.

The semiconductor device 100 may further include first gate capping layers 70 and second gate capping layers 76. The first gate capping layers 70 may be in contact with the first gate electrodes 67, and may be adjacent to the first active patterns 34. The second gate capping layers 76 may be in contact with the second gate electrodes 73, and may be adjacent to the second active patterns 43. The first gate capping layers 70 and the second gate capping layers 76 may extend in the Y-direction along the first gate electrodes 67 and the second gate electrodes 73, respectively.

The first gate capping layers 70 and the second gate capping layers 76 may include silicon oxide, silicon nitride, silicon oxynitride, silicon carbonitride, a low-k dielectric, or a combination thereof. For example, the first gate capping layers 70 and the second gate capping layers 76 may include silicon nitride.

The dielectric structure 55 may cover the vertically spaced channel structures CS. For example, a portion of the dielectric structure 55 may extend between the vertically spaced channel structures CS in the vertical direction. A portion of the dielectric structure 55 may also extend in the X-direction between the first active pattern 34 and the second active pattern 43 and between the first active pattern 34 and the charge storage element 40. A portion of the dielectric structure 55 may extend in the X-direction between the first active pattern 34 and the first gate electrode 67 and between the second active pattern 43 and the second gate electrode 73. A portion of the dielectric structure 55 may extend in the Y-direction between the Y-direction spaced channel structures CS.

In embodiments, the dielectric structure 55 may include a dielectric material layer 37, an insulating structure 52, and a gate dielectric layer 56. For example, a portion of the dielectric structure 55 extending in the X-direction between the first active pattern 34 and the second active pattern 43 and between the first active pattern 34 and the charge storage element 40 may be referred to as a dielectric material layer 37. A portion of the dielectric structure 55 extending in the Y-direction and the vertical direction between the channel structures CS may be referred to as an insulating structure 52. The insulating structure 52 may cover a side surface of the plate electrode 85. In embodiments, a portion of the insulating structure 52 may extend to an upper surface of the substrate 10, and may cover the upper surface of the substrate 10.

A portion of the dielectric structure 55 extending in the X-direction between the first active pattern 34 and the first gate electrode 67 and between the second active pattern 43 and the second gate electrode 73 may be referred to as a gate dielectric layer 56. In this specification, the gate dielectric layer 56 between the first active pattern 34 and the first gate electrode 67 may be referred to as a ‘first gate dielectric layer,’ and the gate dielectric layer 56 between the second active pattern 43 and the second gate electrode 73 may be referred to as a ‘second gate dielectric layer.’

Each of the dielectric material layer 37, the insulating structure 52, and the gate dielectric layer 56 may include at least one of silicon oxide or a high-k dielectric. For example, the high-k dielectric may be formed of, but is not limited to, HfO₂, HfSiO, HfSiON, HfTaO, HfTiO, HfZrO, ZrO₂, Al₂O₃, or a combination thereof. Each of the dielectric material layer 37, the insulating structure 52, and the gate dielectric layer 56 may be formed as a single layer or multiple layers of the aforementioned materials.

The semiconductor device 100 may further include a liner layer 58 and a gapfill layer 62. The gapfill layer 62 may fill a space between the channel structures CS. For example, the gapfill layer 62 may be in contact with the first gate electrodes 67, the second gate electrodes 73, the first gate capping layers 70, the second gate capping layers 76, and the bit lines 82. The liner layer 58 may be in contact with the dielectric structure 55 and the gapfill layer 62, and may extend between the dielectric structure 55 and the gapfill layer 62. The liner layer 58 may be in contact with the first gate electrode 67 and the second gate electrode 73.

The liner layer 58 and the gapfill layer 62 may include silicon oxide, silicon nitride, silicon oxynitride, silicon carbonitride, a low-k dielectric, or a combination thereof. For example, the liner layer 58 may include silicon nitride, and the gapfill layer 62 may include silicon oxide.

The bit lines 82 may extend in the vertical direction, and may be spaced apart from one another in the Y-direction. Each of the bit lines 82 may be in contact with the channel structures CS spaced apart in the vertical direction. For example, the bit lines 82 may be in contact with end portions of the first active patterns 34. For example, when each of the first active patterns 34 includes the first source/drain region SDa and the second source/drain region SDb, the bit lines 82 may be in contact with the first source/drain regions SDa of the first active patterns 34. In embodiments, the first source/drain regions SDa may partially overlap the bit lines 82 in the vertical direction.

The bit lines 82 may also be in contact with end portions of the second active patterns 43, end portions of the first gate capping layers 70, and end portions of the second gate capping layers 76. In embodiments, the second active patterns 43, the first gate capping layers 70, and the second gate capping layers 76 may partially overlap the bit lines 82 in the vertical direction.

The bit lines 82 may include a conductive material, for example, doped single crystal silicon, doped polycrystalline silicon, a metal, a conductive metal nitride, a metal-semiconductor compound, a conductive metal oxide, conductive graphene, carbon nanotubes, or a combination thereof.

The plate electrodes 85 may extend in the vertical direction, and may be spaced apart from one another in the Y-direction. Each of the plate electrodes 85 may be in contact with the channel structures CS spaced apart in the vertical direction. For example, the plate electrodes 85 may be in contact with end portions of the first active patterns 34. For example, when each of the first active patterns 34 includes the first source/drain region SDa and the second source/drain region SDb, the bit lines 82 may be in contact with the second source/drain regions SDb of the first active patterns 34. In embodiments, the second source/drain regions SDb may partially overlap the bit lines 82 in the vertical direction. The plate electrodes 85 may be grounded.

The plate electrodes 85 may include a conductive material, for example, doped single crystal silicon, doped polycrystalline silicon, a metal, a conductive metal nitride, a metal-semiconductor compound, a conductive metal oxide, conductive graphene, carbon nanotubes, or a combination thereof.

The first active pattern 34, the dielectric material layer 37, the charge storage element 40, the second active pattern 43, the gate dielectric layer 56, the first gate electrode 67, and the second gate electrode 73 may form a memory cell MC. The memory cell MC may have a structure identical to or similar to the memory cell MC described with reference to FIG. 1.

According to embodiments, the first gate electrode 67 and the second gate electrode 73 may be disposed to be adjacent to the first active pattern 34 and the second active pattern 43, respectively, and the first gate electrode 67 and the second gate electrode 73 may be disposed to be spaced apart from one another in the vertical direction, with the first active pattern 34 and the second active pattern 43 interposed therebetween. Therefore, electrical coupling between the first gate electrode 67 and the second gate electrode 73 may be reduced, and the gate electrodes 67 and 73 may be easily controlled independently.

In addition, since the bit line 82 extends in the vertical direction, even though the number of channel structures CS stacked in the vertical direction increases, the number of bit lines 82 may not increase, and thus, it may be advantageous for integration of the semiconductor device 100.

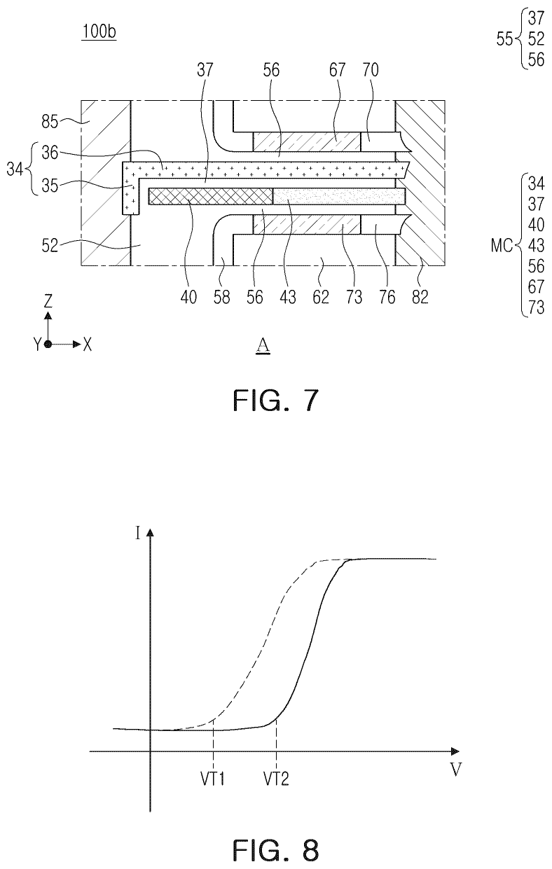

FIGS. 6 and 7 are vertical cross-sectional views of semiconductor devices according to example embodiments.

Referring to FIG. 6, a semiconductor device 100a may include a charge storage element 40 and a first gate electrode 67, overlapping a first active pattern 34 in the vertical direction. In embodiments, the first active pattern 34 may include a first source/drain region SDa, a second source/drain region SDb, and a channel region CH, and the charge storage element 40 may overlap the second source/drain region SDb in the vertical direction. The charge storage element 40 may not overlap vertically with the channel region CH, and may be disposed offset in the X-direction from the channel region CH.

In embodiments, the charge storage element 40 may not overlap the first gate electrode 67 in the vertical direction, and may be disposed offset from the first gate electrode 67 in the X-direction.

Referring to FIG. 7, a semiconductor device 100b may include a charge storage element 40 and a first gate electrode 67, overlapping a first active pattern 34 in the vertical direction. The first active pattern 34 may include a first portion 35 extending in the vertical direction and contacting a plate electrode 85, and a second portion 36 extending in the X-direction from an end portion of the first portion 35. In embodiments, the charge storage element 40 may partially overlap the first gate electrode 67 in the vertical direction. In embodiments, the first active pattern 34 may include an oxide semiconductor material or polycrystalline silicon.

FIG. 8 illustrates I-V curves of active patterns according to the presence or absence of charge storage elements.

Referring to FIG. 8, as illustrated in FIGS. 5 to 7, when a charge storage element 40 overlaps a first active pattern 34 in the vertical direction or overlaps a first gate electrode 67 in the vertical direction, an I-V curve of the first active pattern 34 may be changed. For example, when a charge storage element 40 overlaps a first active pattern 34 in the vertical direction, channel resistance (slope of an I-V curve) of the first active pattern 34 may be changed depending on whether the charge storage element 40 stores charges. When the charge storage element 40 overlaps the first gate electrode 67 in the vertical direction, a threshold voltage of the first active pattern 34 may be changed to VT1 or VT2 depending on whether the charge storage element 40 stores charges. Therefore, the charge storage element 40 may store information or function as a gate of a memory cell MC. As in embodiments, since the charge storage element 40 overlaps the first active pattern 34 and the first gate electrode 67 in the vertical direction, a horizontal width and a material of the charge storage element 40 may be easily adjusted to change the I-V curve of the first active pattern 34.

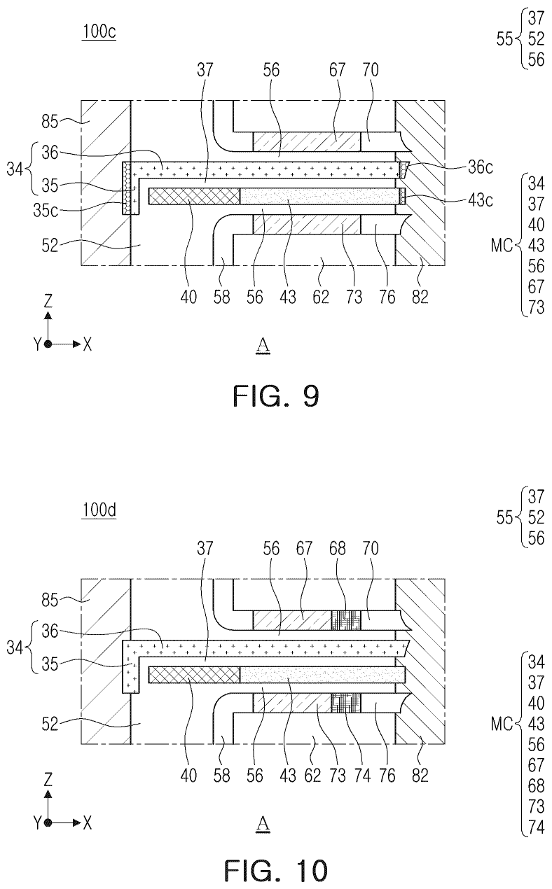

FIGS. 9 to 13 are vertical cross-sectional views of semiconductor devices according to example embodiments.

Referring to FIG. 9, a semiconductor device 100c may include a first active pattern 34 contacting a bit line 82 and a plate electrode 85, and a second active pattern 43 contacting the bit line 82. In embodiments, the first active pattern 34 may include polycrystalline silicon, and may include a first metal-semiconductor compound layer 35c and a second metal-semiconductor compound layer 36c. For example, the first metal-semiconductor compound layer 35c may be disposed between a first portion 35 of the first active pattern 34 and the plate electrode 85, and the second metal-semiconductor compound layer 36c may be disposed between a second portion 36 of the first active pattern 34 and the bit line 82. The first metal-semiconductor compound layer 35c and the second metal-semiconductor compound layer 36c may be formed by depositing a metal-semiconductor compound on the first active pattern 34 or by silicidating a portion of the first active pattern 34. For example, the metal-semiconductor compound may include cobalt silicide (CoSi), titanium silicide (TiSi), nickel silicide (NiSi), tungsten silicide (WSi), or other metal silicides, or may include a nitride such as TiSiN.

In embodiments, the second active pattern 43 may include polycrystalline silicon, and may include a metal-semiconductor compound layer 43c. For example, the metal-semiconductor compound layer 43c may be disposed between the second active pattern 43 and the bit line 82. The metal-semiconductor compound layer 43c may be formed by depositing a metal-semiconductor compound on the second active pattern 43 or by silicidating a portion of the second active pattern 43.

Referring to FIG. 10, a semiconductor device 100d may include a first gate electrode 67 and a second gate electrode 73. In embodiments, the semiconductor device 100d may further include a work function controlling layer 68 between the first gate electrode 67 and a first gate capping layer 70, and a work function controlling layer 74 between the second gate electrode 73 and a second gate capping layer 76. The work function controlling layer 68 and the work function controlling layer 74 may be disposed at least partially at the same level as the first gate electrode 67 and the second gate electrode 73, respectively, and may extend in the Y-direction. The work function controlling layer 68 and the work function controlling layer 74 may overlap a first active pattern 34 and a second active pattern 43 in the vertical direction, respectively.

The work function controlling layer 68 and the work function controlling layer 74 may be used to control a threshold voltage of a read transistor Rtr and a threshold voltage of a write transistor Wtr. For example, the work function controlling layer 68 and the work function controlling layer 74 may include a different material from the first gate electrode 67 and the second gate electrode 73, and may include a material having a different work function from the first gate electrode 67 and the second gate electrode 73. In embodiments, the work function controlling layer 68 and the work function controlling layer 74 may include at least one of a metal, a metal nitride, or polycrystalline silicon. For example, the work function controlling layer 68 and the work function controlling layer 74 may include at least one of Ti, Ta, W, TiN, TaN, WN, or polycrystalline silicon. The work function controlling layer 68 and the work function controlling layer 74 may further include a work function control element, and the work function control element may include at least one of La, Sr, Sb, Y, Al, Ta, Hf, Ir, Zr, or Mg. In embodiments, the work function controlling layer 68 and the work function controlling layer 74 may include materials having different work functions.

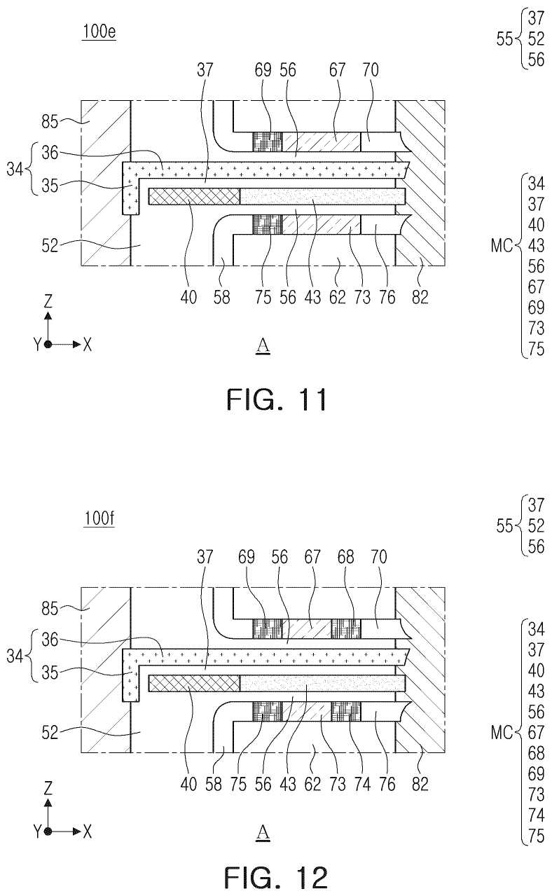

Referring to FIG. 11, a semiconductor device 100e may include a first gate electrode 67 and a second gate electrode 73. In embodiments, the semiconductor device 100e may further include a work function controlling layer 69 between the first gate electrode 67 and a liner layer 58, and a work function controlling layer 75 between the second gate electrode 73 and the liner layer 58. The work function controlling layer 69 and the work function controlling layer 75 may overlap a first active pattern 34 and a second active pattern 43 in the vertical direction, respectively.

The work function controlling layer 69 and the work function controlling layer 75 may be used to control a threshold voltage of a read transistor Rtr and a threshold voltage of a write transistor Wtr. For example, the work function controlling layer 69 and the work function controlling layer 75 may include a different material from the first gate electrode 67 and the second gate electrode 73, and may include a material having a different work function from the first gate electrode 67 and the second gate electrode 73.

Referring to FIG. 12, a semiconductor device 100f may include a first gate electrode 67 and a second gate electrode 73. In embodiments, the semiconductor device 100f may include work function controlling layers 68, 69, 74, and 75, as described with reference to FIGS. 10 and 11. The work function controlling layers 68, 69, 74, and 75 may include a material having a different work function from the first gate electrode 67 and the second gate electrode 73. In embodiments, each of the work function controlling layers 68, 69, 74, and 75 may include a material having a different work function. In the present specification, the work function controlling layers 68 and 69 may be referred to as upper work function controlling layers, and the work function controlling layers 74 and 75 may be referred to as lower work function controlling layers.

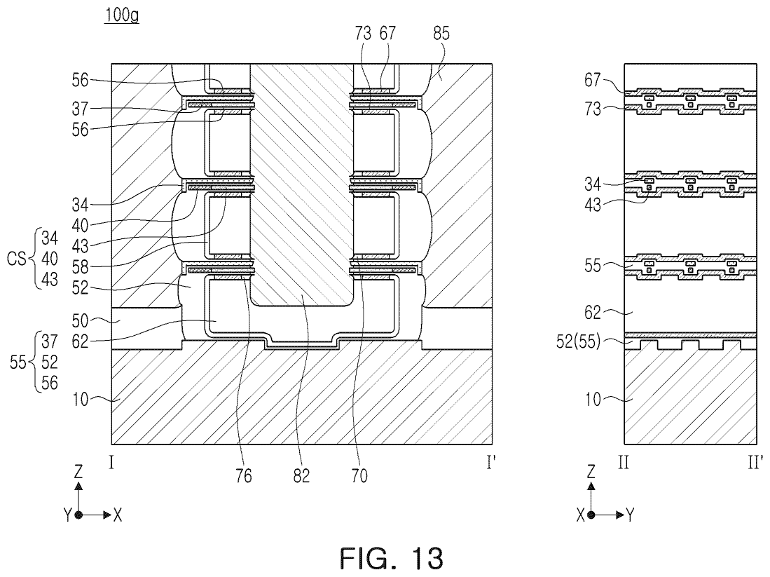

Referring to FIG. 13, a semiconductor device 100g may include a plate electrode 85 contacting channel structures CS. In embodiments, a side surface of the plate electrode 85 may include a concave curved surface. For example, a side surface of the plate electrode 85 may include concave curved surfaces between the channel structures CS. In embodiments, side surfaces of insulating structures 52 of a dielectric structure 55 may include convex curved surfaces between the structures CS.

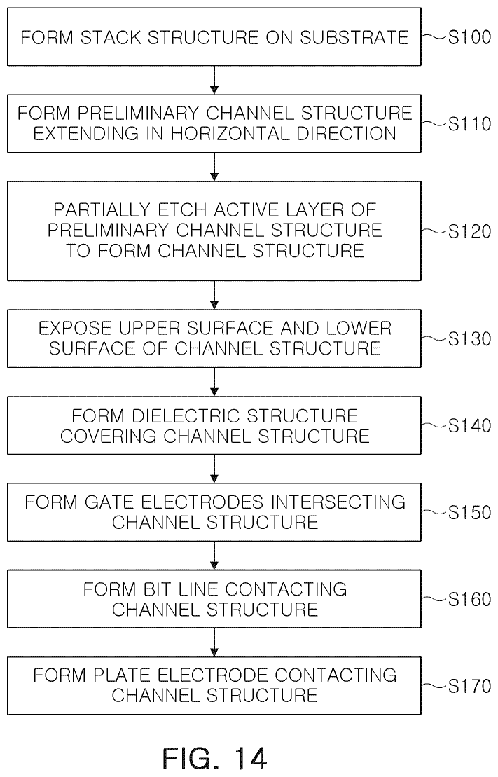

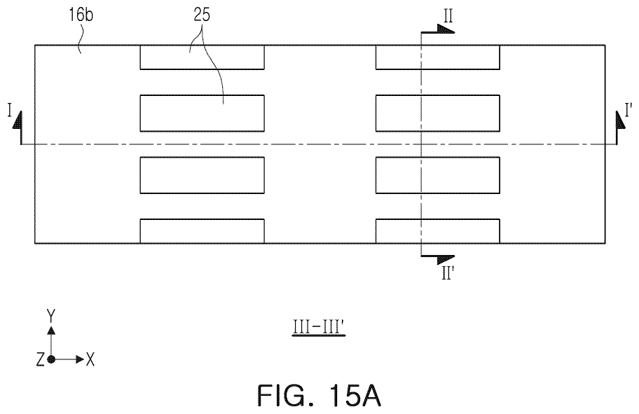

FIG. 14 is a flow chart illustrating a method for manufacturing a semiconductor device according to example embodiments.

Referring to FIG. 14, in embodiments, a method for manufacturing a semiconductor device may include forming a stack structure on a substrate (S100), forming a preliminary channel structure extending in a horizontal direction (S110), partially etching an active layer of the preliminary channel structure to form a channel structure (S120), exposing an upper surface and a lower surface of the channel structure (S130), forming a dielectric structure covering the channel structure (S140), forming gate electrodes intersecting the channel structure (S150), forming a bit line contacting the channel structure (S160), and forming a plate electrode contacting the channel structure (S170).

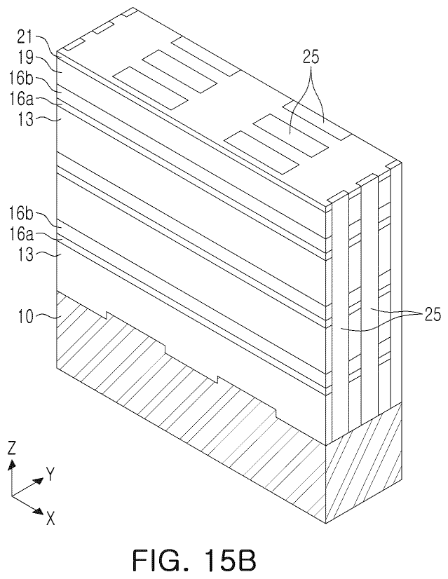

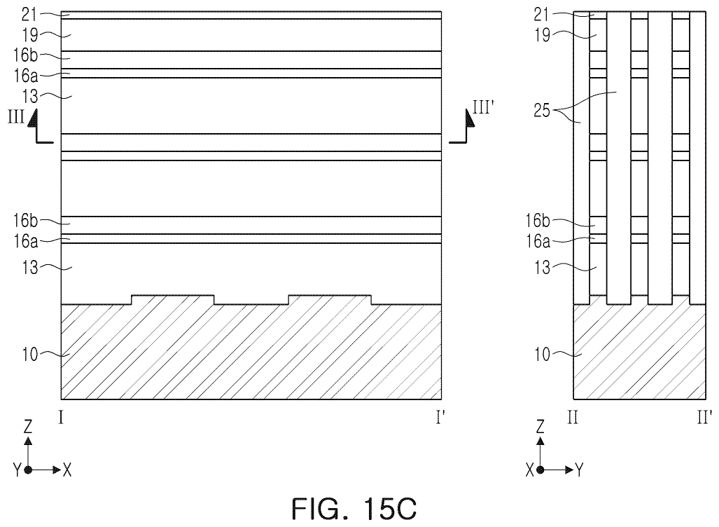

FIGS. 15A to 25C are plan views, perspective views, and vertical cross-sectional views according to a process sequence to illustrate a method for manufacturing a semiconductor device according to example embodiments. Specifically, FIGS. 15A, 16A, 17A, 18A, 19A, 20A, 21A, 22A, 23A, 24A, and 25A are plan views corresponding to FIG. 2. FIGS. 15B, 16B, 17B, 18B, 19B, 20B, 21B, 22B, 23B, 24B, and 25B are perspective views corresponding to FIG. 3. FIGS. 15C, 16C, 17C, 18C, 19C, 20C, 21C, 22C, 23C, 24C, and 25C are vertical cross-sectional views corresponding to FIG. 4.

Referring to FIGS. 15A to 15C, a stack structure (13, 16a, and 16b) may be formed on a substrate 10 (S100). The substrate 10 may include a semiconductor material, such as a group IV semiconductor, a group III-V compound semiconductor, or a group II-VI compound semiconductor.

The stack structure (13, 16a, and 16b) may include insulating layers 13, first sacrificial layers 16a, and second sacrificial layers 16b. The insulating layers 13, the first sacrificial layers 16a, and the second sacrificial layers 16b may be sequentially and repeatedly stacked. For example, the stack structure (13, 16a, and 16b) may be formed by repeatedly stacking a structure in which the insulating layer 13, the first sacrificial layer 16a, and the second sacrificial layer 16b are sequentially stacked.

The insulating layers 13, the first sacrificial layers 16a, and the second sacrificial layers 16b may include materials having etch selectivities with respect to one another. For example, the insulating layers 13 and the first sacrificial layers 16a may include silicon oxide, silicon nitride, silicon oxynitride, silicon carbonitride, a low-k dielectric, or a combination thereof. In embodiments, the insulating layers 13 may include silicon oxide, and the first sacrificial layers 16a may include silicon nitride. In embodiments, the second sacrificial layers 16b may include polysilicon.

The method may further include forming mold layers 19 and 21 on the stack structure (13, 16a, and 16b), and forming sacrificial patterns 25 in the stack structure (13, 16a, and 16b).

The mold layer 19 and the mold layer 21 may be sequentially stacked on the stack structure (13, 16a, and 16b). The mold layer 19 and the mold layer 21 may include silicon oxide, silicon nitride, silicon oxynitride, silicon carbonitride, a low-k dielectric, or a combination thereof.

The sacrificial patterns 25 may be formed by forming holes penetrating the stack structure (13, 16a, and 16b) and the mold layers 19 and 21, and then filling the holes with an insulating material. In the process of forming the holes, an upper surface of the substrate 10 may be partially etched. The sacrificial patterns 25 may extend in the X-direction and the vertical direction, and may be spaced apart from one another in the X-direction and the Y-direction. The sacrificial patterns 25 may include silicon oxide, silicon nitride, silicon oxynitride, silicon carbonitride, a low-k dielectric, or a combination thereof. For example, the sacrificial patterns 25 may include silicon nitride.

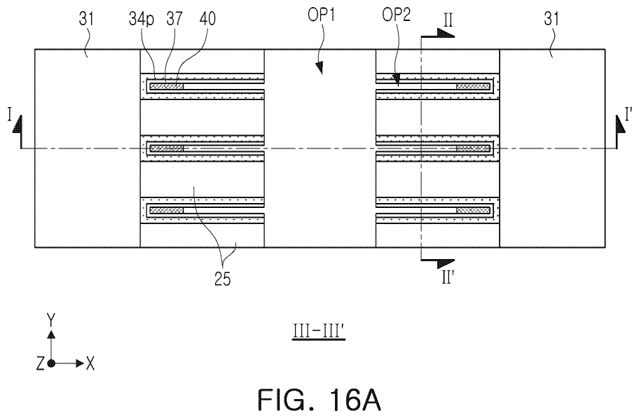

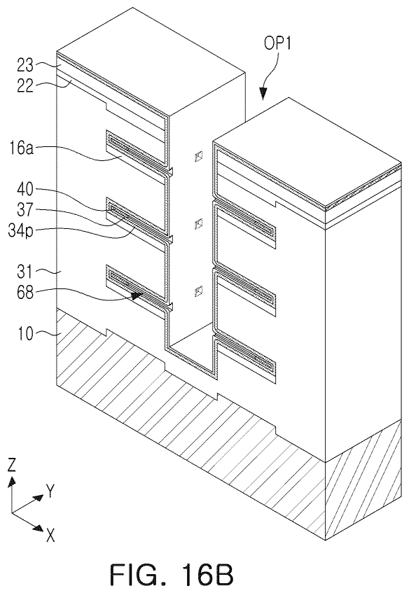

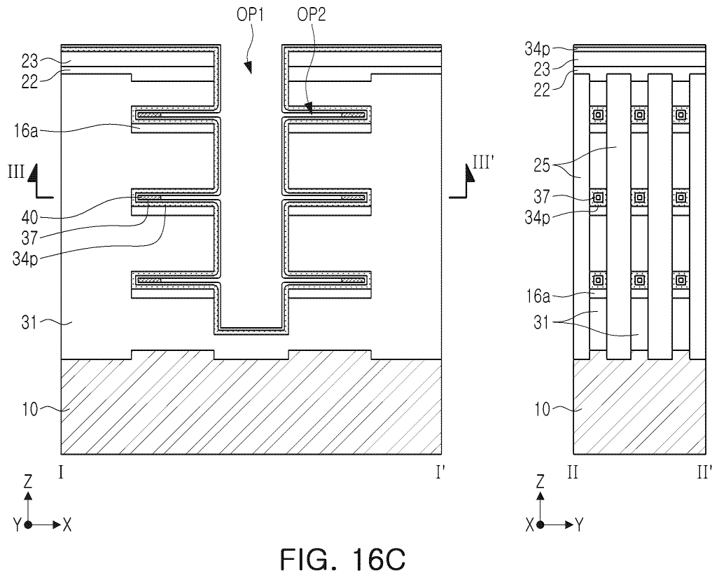

Referring to FIGS. 16A to 16C, the method may further include forming an insulating layer 31, a mold layer 22, and a mold layer 23. After the stack structure (13, 16a, and 16b), the mold layers 19 and 21, and the sacrificial patterns 25 may be anisotropically etched, an insulating material layer may be formed. The insulating material layer may include the same material as the insulating layers 13, and the insulating material layer and the insulating layers 13 may form the insulating layer 31 covering the first sacrificial layers 16a and the second sacrificial layers 16b.

After forming the insulating layer 31, the insulating material layer may be deposited on the sacrificial patterns 25 and the insulating layer 31. The insulating material layer may include the same material as the mold layer 21, and the insulating material layer may form the mold layer 22, together with the mold layer 21. The mold layer 22 may cover the sacrificial patterns 25 and the insulating layer 31. The mold layer 23 may be formed on the mold layer 22. The mold layer 23 may include silicon nitride.

The method may further include forming a first opening OP1 extending in the vertical direction, and second openings OP2 communicating with the first opening OP1 and extending in the X-direction, in the stack structure (13, 16a, and 16b), and forming a first active layer 34p, a dielectric material layer 37, and charge storage elements 40 in the second openings OP2.

The first opening OP1 may be formed by anisotropically etching the first sacrificial layers 16a, the second sacrificial layers 16b, the mold layer 22, and the mold layer 23. The first opening OP1 may expose side surfaces of the first sacrificial layers 16a and side surfaces of the second sacrificial layers 16b. The second openings OP2 may be formed by removing the exposed second sacrificial layers 16b. Since the insulating layer 31 and the first sacrificial layers 16a have etching selectivity with respect to the second sacrificial layers 16b, the second sacrificial layers 16b may be selectively removed. The second openings OP2 may extend in the X-direction, and may be spaced apart from one another in the Y-direction and the vertical direction.

The first active layer 34p may be conformally formed along an inner wall of the first opening OP1 and inner walls of the second openings OP2, and may cover an upper surface of the mold layer 23. The dielectric material layer 37 may be conformally formed on the first active layer 34p. The first active layer 34p and the dielectric material layer 37 may partially fill the second openings OP2.

The charge storage elements 40 may be formed by depositing a conductive material on the dielectric material layer 37, in the first opening OP1 and the second openings OP2, and partially etching the conductive material. The etched conductive material may remain in the second openings OP2 to form the charge storage elements 40.

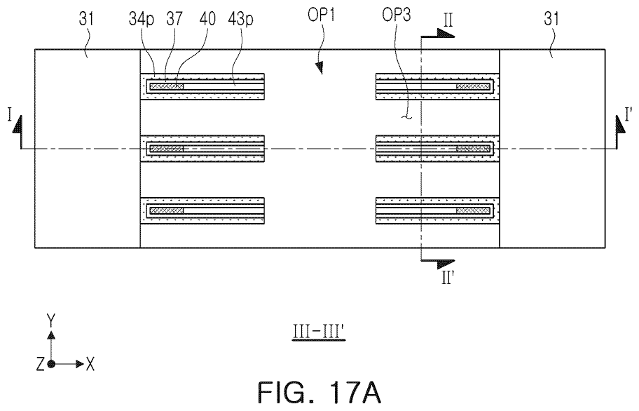

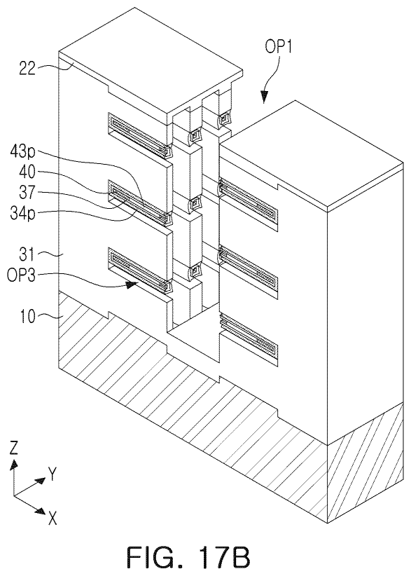

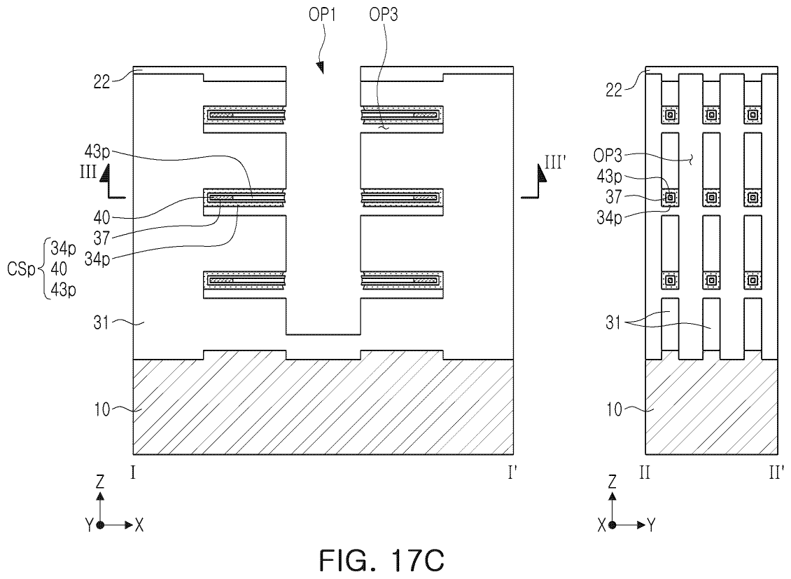

Referring to FIGS. 17A to 17C, second active layers 43p may be deposited in the second openings OP2 to form a preliminary channel structure CSp (S110). For example, an active material layer may be formed in the second openings OP2 to contact the dielectric material layer 37 and the charge storage elements 40, and then the active material layer may be partially etched to form the second active layers 43p. Thereafter, the dielectric material layer 37 and the first active layer 34p may be sequentially partially etched.

The second active layer 43p, the charge storage element 40 contacting an end portion of the second active layer 43p, and the first active layer 34p surrounding the second active layer 43p and the charge storage element 40 may form the preliminary channel structure CSp. For example, the forming a preliminary channel structure CSp (S110) may include forming the first active layer 34p, the charge storage element 40, and the second active layer 43p in the second opening OP2, as described with reference to FIGS. 16A to 17C. The preliminary channel structures CSp may be disposed in the second openings OP2. The preliminary channel structures CSp may extend in the X-direction, and may be spaced apart from one another in the X-direction, the Y-direction, and the vertical direction. The preliminary channel structures CSp may be disposed symmetrically with respect to the first opening OP1.

The method may further include forming third openings OP3 by selectively removing the first sacrificial layers 16a and the sacrificial patterns 25. The third openings OP3 may expose lower surfaces and side surfaces of the preliminary channel structures CSp. Upper surfaces of the preliminary channel structures CSp may be in contact with the insulating layer 31, and may not be exposed.

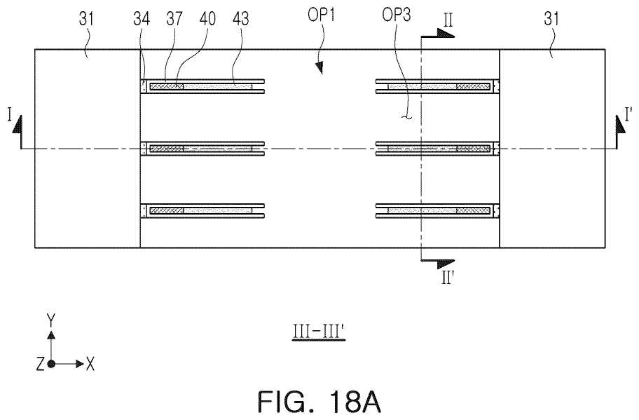

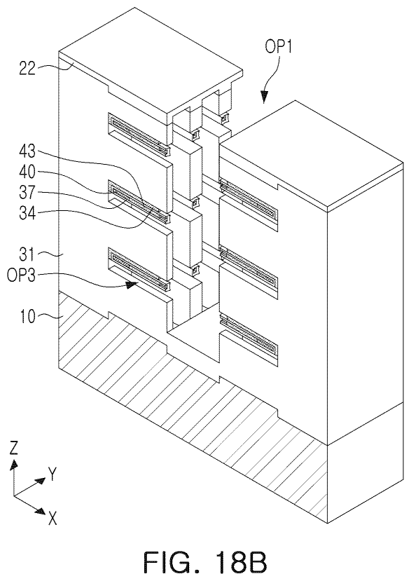

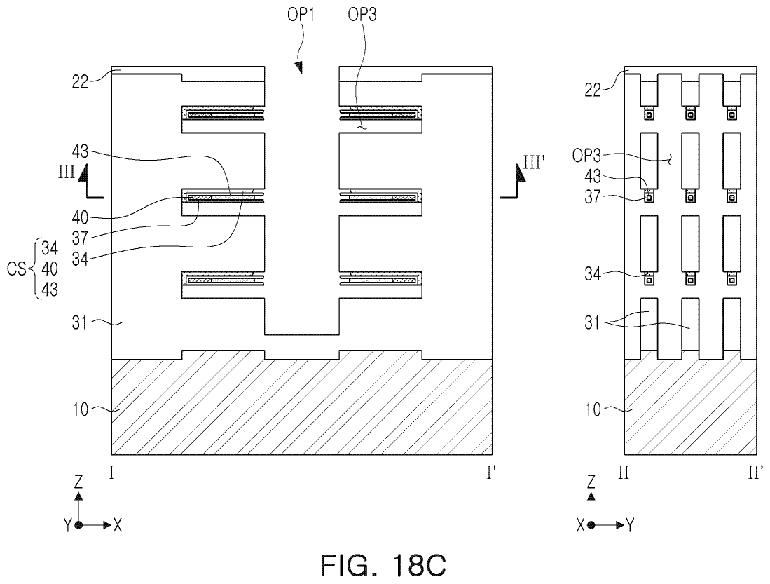

Referring to FIGS. 18A to 18C, the active layers 34p and 43p of the preliminary channel structures CSp may be partially etched to form a channel structure (S120). For example, the first active layers 34p and the second active layers 43p exposed by the first openings OP1 and the third openings OP3 may be partially etched. In embodiments, the first active layers 34p and the second active layers 43p may include the same material, and may be etched simultaneously. In embodiments, the first active layers 34p and the second active layers 43p may include different materials, and may be etched separately by separate etching processes.

The first active layers 34p may have portions exposed by the first opening OP1 and the third openings OP3 etched, and portions of the first active layers 34p contacting the insulating layer 31 may not be etched. The first active layers 34p may be etched to form first active patterns 34, and the first active patterns 34 may have a folded shape extending along the insulating layer 31. For example, the first active patterns 34 may include portions extending in the X-direction and portions extending in the vertical direction. The first active layers 34p may be etched to expose the dielectric material layers 37 by the third openings OP3.

Portions of the second active layers 43p exposed to the first opening OP1 may be etched to form second active patterns 43. The first active pattern 34, the charge storage element 40, and the second active pattern 43 may form a channel structure CS.

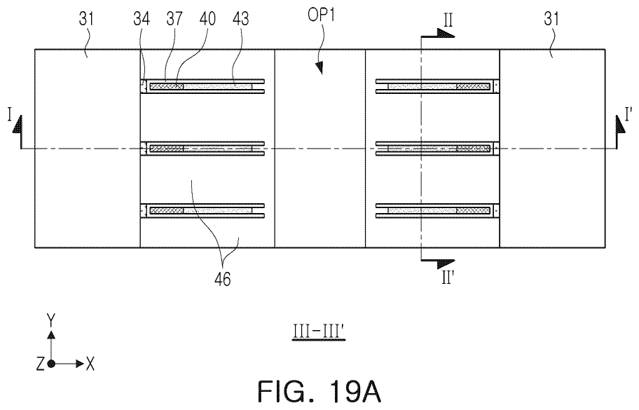

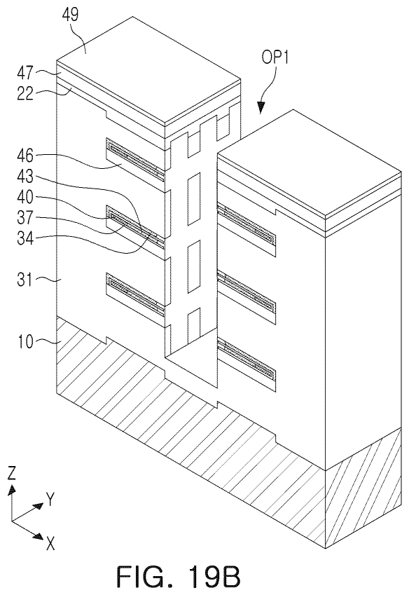

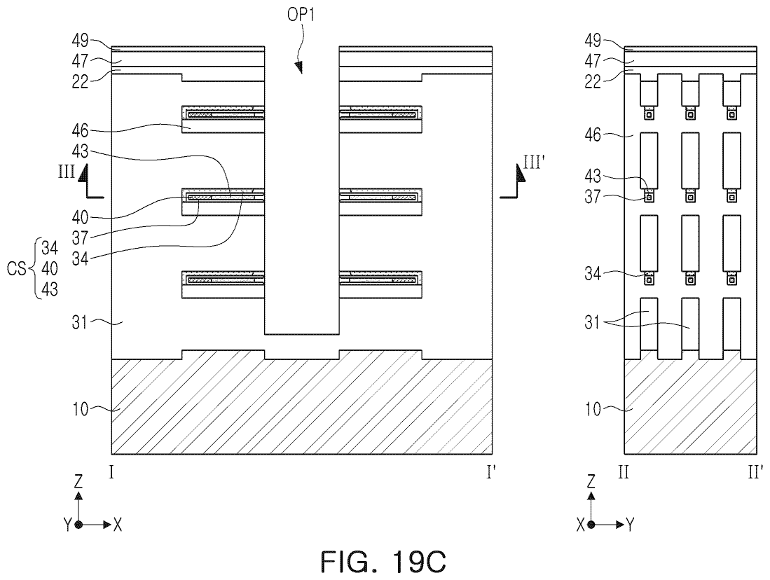

Referring to FIGS. 19A to 19C, the method may further include forming sacrificial layers 46 covering the channel structures CS. For example, an insulating material layer may be deposited in the first opening OP1 and the third openings OP3 and on the mold layer 22, a mask layer 49 may be formed on the insulating material layer, and the mask layer 49 and the insulating material layer may be anisotropically etched to form the sacrificial layers 46. The insulating material layer covering the mold layer 22 may be etched to form an insulating material layer 47.

The sacrificial layers 46 and the insulating material layer 47 may include a material having etching selectivity with respect to the insulating layer 31. For example, the sacrificial layers 46 and the insulating material layer 47 may include silicon nitride.

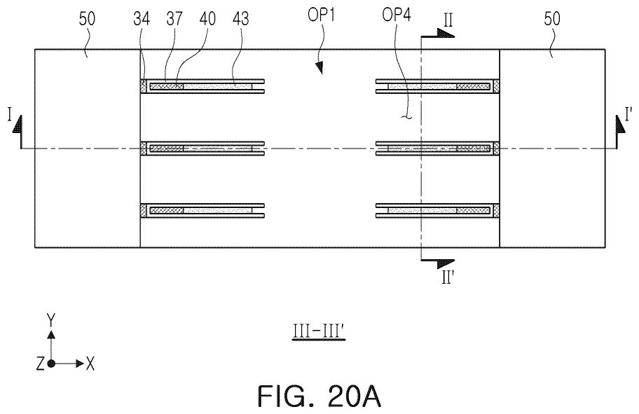

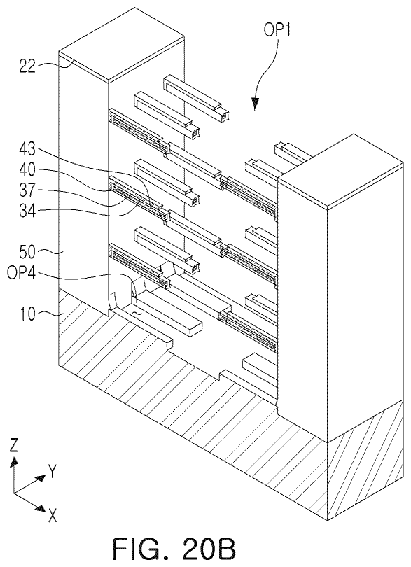

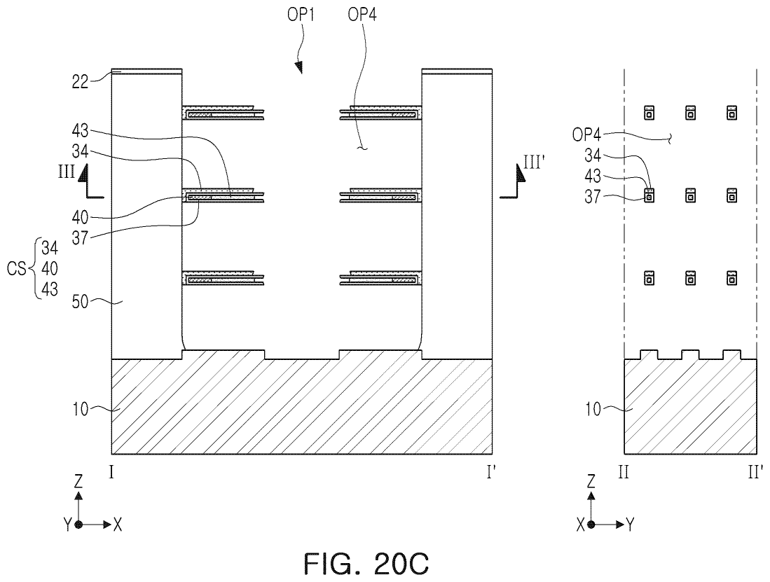

Referring to FIGS. 20A to 20C, upper and lower surfaces of the channel structures CS may be exposed (S130). For example, the insulating layer 31 may be etched to form an insulating layer 50. The sacrificial layers 46 may be removed to form fourth openings OP4, and the insulating material layer 47 and the mask layer 49 may be removed. In embodiments, a side surface of the insulating layer 50 may include concave curves between the channel structures CS.

End portions of the channel structures CS may be in contact with the insulating layers 50, and portions of the channel structures CS from which the end portions are excluded may be exposed by the first opening OP1 and the fourth openings OP4.

In embodiments, a doping process may be performed before forming the insulating layers 50. For example, the insulating layer 31 may be partially etched to partially expose the first active patterns 34. A doping process, such as gas phase doping, may be performed on a portion of the exposed first active patterns 34, and first source/drain regions Sda, as described with reference to FIG. 5, may be formed. In embodiments, the doping process may be omitted when the first active patterns 34 include an oxide semiconductor material.

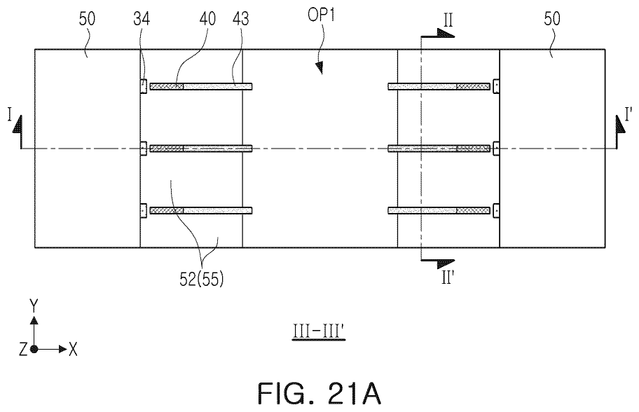

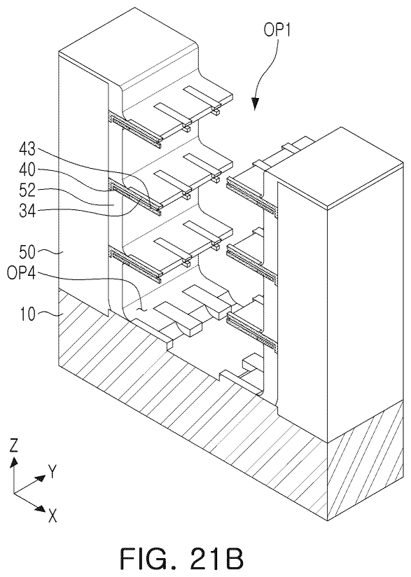

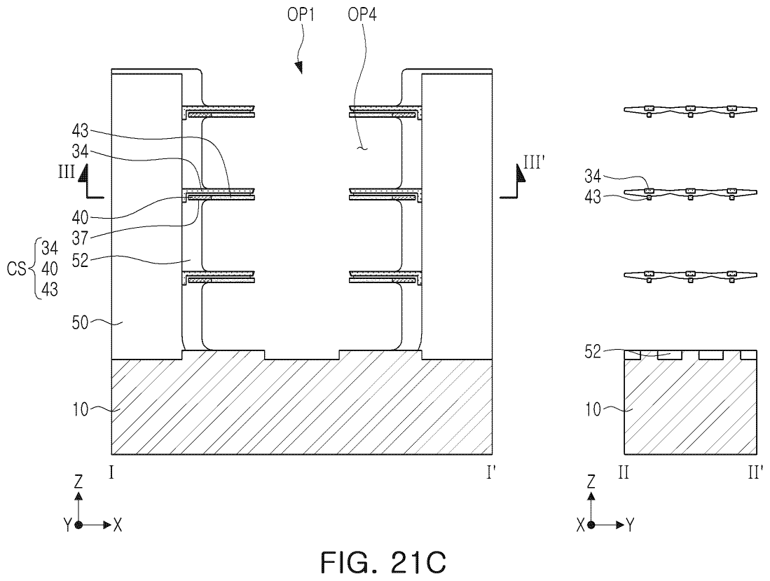

Referring to FIGS. 21A to 21C, the method may further include forming insulating structures 52 partially covering the channel structures CS. For example, after forming an insulating material layer to cover the channel structures CS, the insulating material layer may be etched to expose the first active patterns 34 and the second active patterns 43, thereby forming insulating structures 52. The insulating structures 52 may extend in the vertical direction, and may cover the insulating layers 50. The insulating structures 52 may not completely cover an upper surface of the substrate 10, and a portion of the upper surface of the substrate 10 may be exposed by the first opening OP1.

In the etching process, a portion of the dielectric material layers 37 covering lower surfaces of the second active patterns 43 may be etched, and the lower surfaces of the second active patterns 43 may be exposed. In embodiments, the insulating structures 52 may include the same material as the dielectric material layers 37, and an interface between the insulating structures 52 and the dielectric material layers 37 may not be observed.

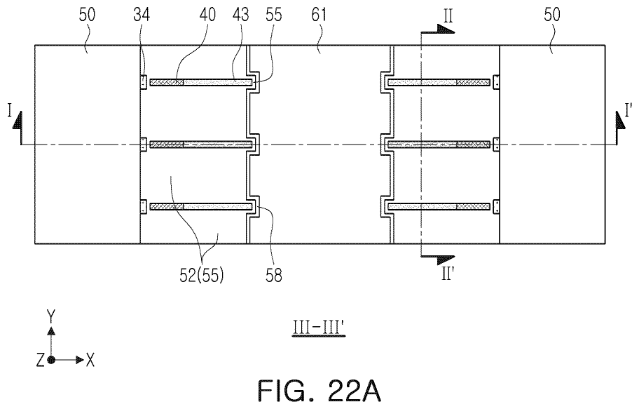

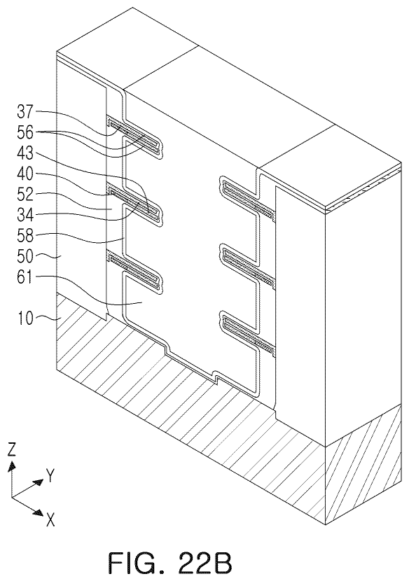

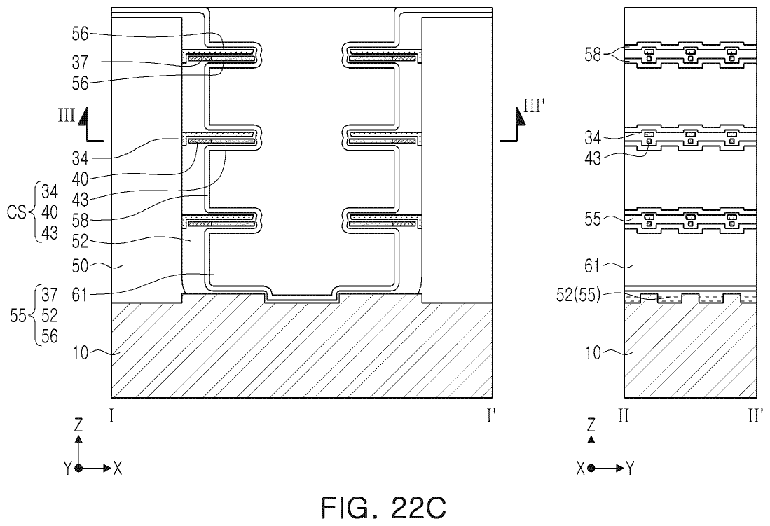

Referring to FIGS. 22A to 22C, dielectric structures 55 covering the channel structures CS may be formed (S140). For example, gate dielectric layers 56 covering the channel structures CS and the insulating structures 52 may be formed. The gate dielectric layers 56 may cover the first active patterns 34 and the second active patterns 43, and may be in contact with the dielectric material layers 37 between the first active patterns 34 and the second active patterns 43. Each of the gate dielectric layers 56 may extend in the vertical direction, and may cover a plurality of first active patterns 34 and a plurality of second active patterns 43.

The dielectric material layer 37, the insulating structure 52, and the gate dielectric layer 56 may form a dielectric structure 55. For example, forming the dielectric structure 55 (S140) may include forming the insulating structure 52 and forming the gate dielectric layer 56, described with reference to FIGS. 21A to 22C.

In embodiments, the gate dielectric layers 56 may include the same material as the insulating structures 52 and the dielectric material layers 37, and no interface between the gate dielectric layers 56, the insulating structures 52, and the dielectric material layers 37 may be observed. In embodiments, a portion of the dielectric structures 55 may extend along the upper surface of the substrate 10, and may cover the upper surface of the substrate 10.

The method may further include forming a liner layer 58 and a gapfill layer 61 on the dielectric structures 55. For example, the liner layer 58 may be conformally formed on the dielectric structures 55. The gapfill layer 61 may be formed on the liner layer 58, and may fill a space between the channel structures CS. After forming the gapfill layer 61, a process of planarizing the gapfill layer 61 to expose the liner layer 58 may be further performed.

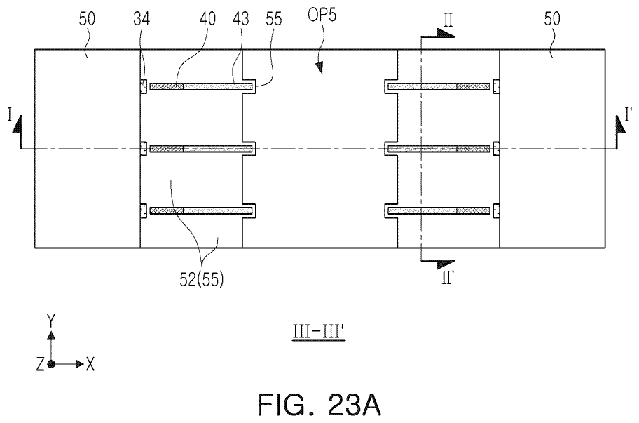

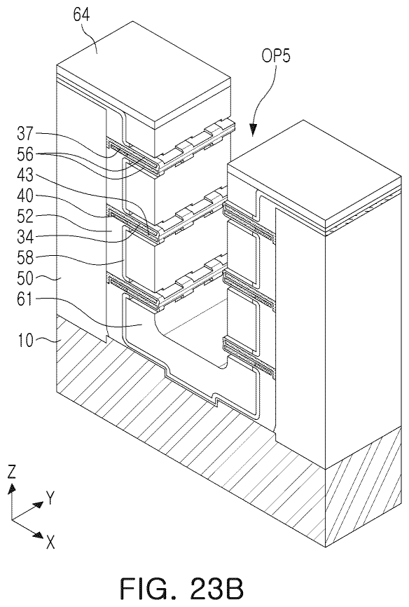

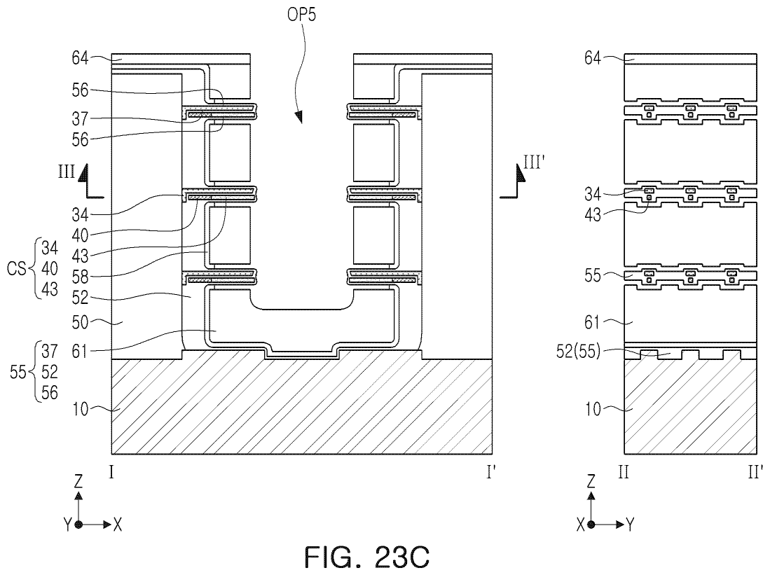

Referring to FIGS. 23A to 23C, the method may further include etching the gapfill layer 61 to form a fifth opening OP5, and etching the liner layer 58. For example, a mask layer 64 may be formed on the liner layer 58 and the gapfill layer 61, and the gapfill layer 61 and the mask layer 64 may be anisotropically etched. Thereafter, the gapfill layer 61 may be selectively etched to expose the liner layer 58. The exposed liner layer 58 may be selectively etched to form a plurality of liner layers 58 covering the dielectric structures 55. Portions of the dielectric structures 55 may be exposed by the fifth opening OP5.

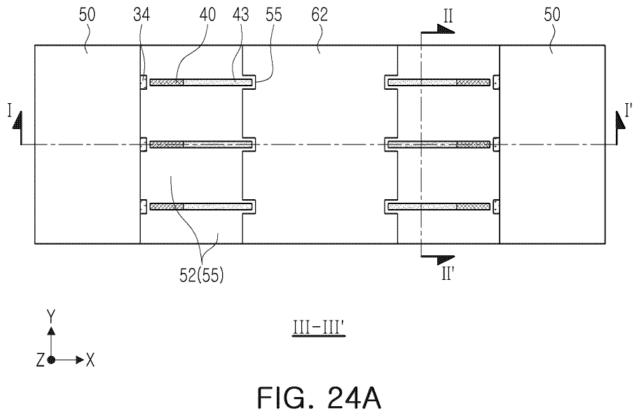

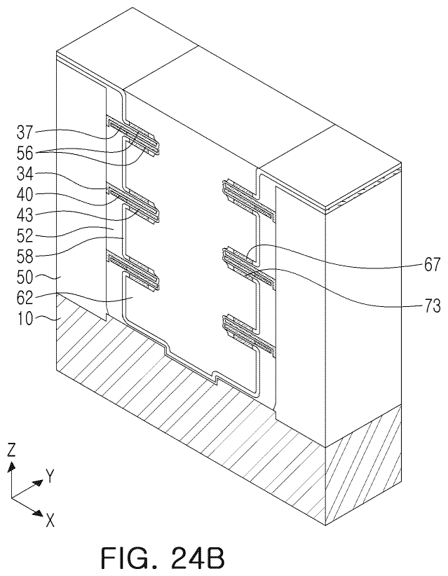

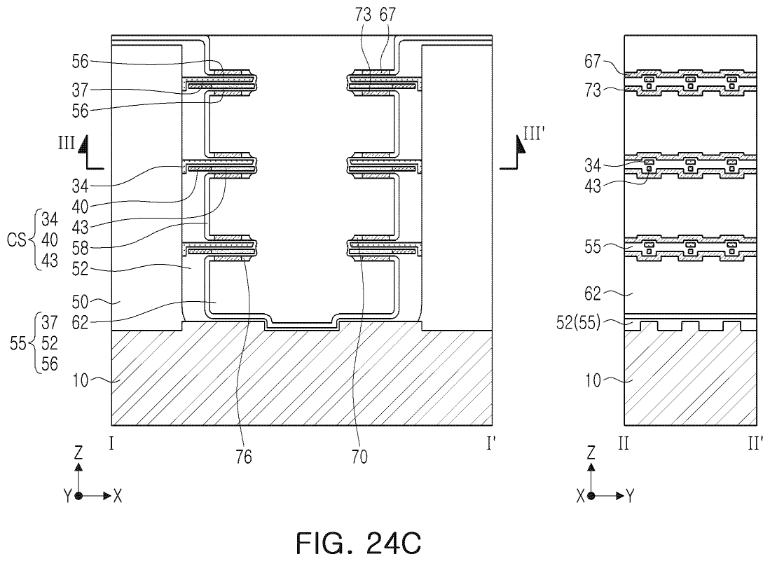

Referring to FIGS. 24A to 24C, gate electrodes 67 and 73 intersecting the channel structures CS may be formed (S150). For example, gate electrodes 67 and 73 overlapping the channel structures CS in the vertical direction and extending in the Y-direction may be formed in a space from which the liner layer 58 is partially removed. The gate electrodes 67 and 73 may be formed by depositing a conductive material to cover portions of the dielectric structures 55 exposed by the fifth opening OP5, and then etching back the conductive material. The gate electrodes 67 and 73 may extend in the Y-direction, and may be spaced apart from one another in the X-direction and the vertical direction.

The gate electrodes 67 and 73 may include first gate electrodes 67 and second gate electrodes 73. The first gate electrodes 67 and the second gate electrodes 73 may be spaced apart from one another in the vertical direction, with the channel structures CS interposed therebetween. For example, the first gate electrodes 67 may be adjacent to the first active patterns 34, and may at least partially overlap the first active patterns 34 in the vertical direction. The second gate electrodes 73 may be adjacent to the second active patterns 43, and may at least partially overlap the second active patterns 43 in the vertical direction.

The method may further include forming gate capping layers 70 and 76 contacting the gate electrodes 67 and 73, and forming a gapfill layer 62 filling the fifth opening OP5. The gate capping layers 70 and 76 may be formed by depositing an insulating material layer to cover the gate electrodes 67 and 73 and then etching the insulating material layer. The gate capping layers 70 and 76 may extend in the Y-direction, and may be spaced apart from one another in the X-direction and the vertical direction.

The gate capping layers 70 and 76 may include first gate capping layers 70 and second gate capping layers 76. The first gate capping layers 70 and the second gate capping layers 76 may be spaced apart from one another in the vertical direction, with the channel structures CS interposed therebetween. For example, the first gate capping layers 70 may be in contact with the first gate electrodes 67, and may be adjacent to the first active patterns 34. The second gate capping layers 76 may be in contact with the second gate electrodes 73, and may be adjacent to the second active patterns 43.

After forming an insulating material layer on the gapfill layer 61 to fill the fifth opening OP5, a process of planarizing the insulating material layer to expose a portion of the dielectric structure 55 may be performed to form a gapfill layer 62.

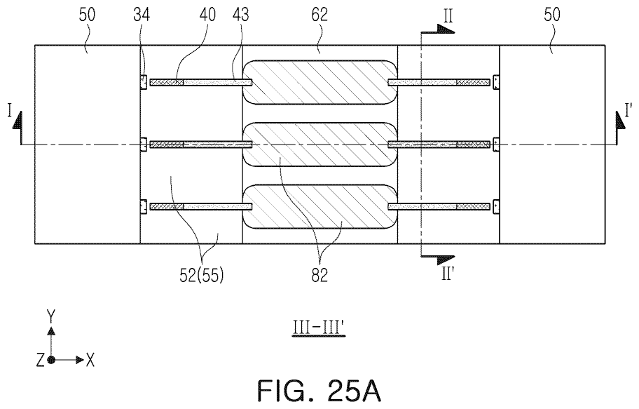

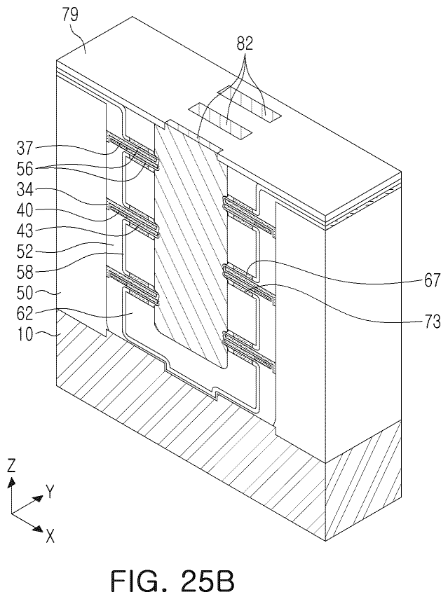

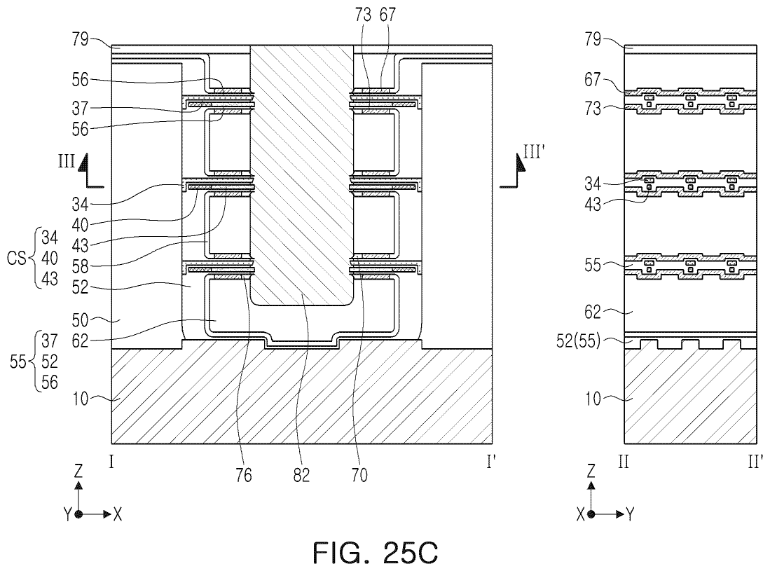

Referring to FIGS. 25A to 25C, bit lines 82 contacting the channel structures CS may be formed in the gapfill layer 62 (S160). For example, a mask layer 79 covering upper surfaces of the dielectric structures 55 and an upper surface of the gapfill layer 62 may be formed, and the mask layer 79 and the gapfill layer 62 may be anisotropically etched, and then a conductive material may be filled to form bit lines 82. The bit lines 82 may extend in the vertical direction, and may be spaced apart from one another in the Y-direction.

The bit lines 82 may be in contact with end portions of the channel structures CS. For example, the bit lines 82 may be in contact with the first active patterns 34 and the second active patterns 43. In embodiments, the bit lines 82 may also be in contact with the first gate capping layers 70 and the second gate capping layers 76. In embodiments, a metal-semiconductor compound, such as a silicide material, may be formed in end portions of the first active patterns 34 and end portions of the second active patterns 43 before forming the bit lines 82. In embodiments, when the first active patterns 34 and the second active patterns 43 include an oxide semiconductor material, a process of forming the metal-semiconductor compound may be omitted.

Referring again to FIGS. 2 to 5, plate electrodes 85 contacting the channel structures CS may be formed (S170). For example, plate electrodes 85 may be formed by filling a conductive material after anisotropic etching of the insulating layer 50. The plate electrodes 85 may extend in the vertical direction, and may be spaced apart from one another in the Y-direction.

The plate electrodes 85 may be in contact with end portions of the channel structures CS. For example, the plate electrodes 85 may be in contact with the first active patterns 34, and may be spaced apart from the second active patterns 43. In embodiments, before forming the plate electrodes 85, a doping process such as vapor phase doping may be performed on a portion of the exposed first active patterns 34, and second source/drain regions SDb, as described with reference to FIG. 5, may be formed. In addition, a metal-semiconductor compound such as a silicide material may be formed on end portions of the first active patterns 34. In embodiments, when the first active patterns 34 include an oxide semiconductor material, the doping process and the process of forming the metal-semiconductor compound may be omitted.

After the plate electrodes 85 may be formed, the mask layer 79 may be removed and a planarization process may be performed to expose the gapfill layer 62, to manufacture a semiconductor device 100.

According to embodiments of the technical idea of the present disclosed concepts, a first gate electrode and a second gate electrode may be respectively disposed to be adjacent to a first active pattern and a second active pattern. The first gate electrode and the second gate electrode may be spaced apart in a vertical direction, with the first active pattern and the second active pattern interposed therebetween, to be independently controlled.

A method for manufacturing a semiconductor device according to example embodiments includes forming a stack structure on a substrate; forming a preliminary channel structure extending in a first horizontal direction in an opening in the stack structure; partially etching an active layer of the preliminary channel structure to form a channel structure; forming a dielectric structure covering the channel structure; forming gate electrodes extending in a second horizontal direction, intersecting the channel structure and the first horizontal direction, and overlapping one another in a vertical direction; and forming a bit line contacting the channel structure and extending in the vertical direction.

The stack structure may include a first active layer, a second active layer, and a charge storage element, wherein the charge storage element may be in contact with an end portion of the second active layer, and the first active layer may surround the second active layer and the charge storage element, and may extend in the first horizontal direction and the vertical direction.

The forming a preliminary channel structure may include partially etching the first active layer and the second active layer to form a first active pattern and a second active pattern.

The first active pattern may include a first portion extending in the vertical direction, and a second portion extending from an end portion of the first portion in the first horizontal direction.

The gate electrodes may include a first gate electrode overlapping a first active pattern of the channel structure in the vertical direction, and a second gate electrode overlapping a second active pattern of the channel structure in the vertical direction.

The method may further include, before the forming gate electrodes, forming a liner layer and a gapfill layer covering the dielectric structure; and partially removing the liner layer to expose the dielectric structure. The gate electrodes may be formed by depositing a conductive material on the exposed dielectric structure.

The method may further include, after the forming gate electrodes, forming gate capping layers at a same level as a level of the gate electrodes.

The bit line may be formed in the gapfill layer.

The method may further include forming a plate electrode spaced apart from the bit line in the first horizontal direction and contacting the channel structure.

The method may further include, before the forming a bit line, performing a doping process on a first active pattern of the channel structure.

Various advantages and effects of the present disclosed concepts are not limited to the above-described contents, and will be more easily understood in the process of explaining specific embodiments.

While example embodiments have been illustrated and described above, it will be apparent to those skilled in the art that modifications and variations could be made without departing from the scope of the present disclosed concepts as defined by the appended claims.

What is claimed is:

1. A semiconductor device comprising:
a first active pattern extending on a substrate in a first horizontal direction;
a first gate electrode at least partially overlapping the first active pattern in a vertical direction and adjacent to the first active pattern;
a second active pattern extending in the first horizontal direction, wherein the second active pattern includes a first surface and a second surface, spaced apart from the first surface in the first horizontal direction;
a bit line contacting the first surface of the second active pattern and extending in the vertical direction;
a charge storage element contacting the second surface of the second active pattern; and
a second gate electrode at least partially overlapping the second active pattern in the vertical direction and adjacent to the second active pattern,
wherein the first gate electrode and the second gate electrode are spaced apart from one another in the vertical direction, with the first active pattern and the second active pattern interposed therebetween.

2. The semiconductor device of claim 1, wherein the first active pattern includes a first portion extending in the vertical direction, and a second portion extending in the first horizontal direction from an end portion of the first portion.

3. The semiconductor device of claim 2, wherein the charge storage element is disposed between the first portion of the first active pattern and the second active pattern.

4. The semiconductor device of claim 2, wherein the first active pattern includes a first metal-semiconductor compound layer on the first portion and a second metal-semiconductor compound layer disposed on the second portion and contacting the bit line.

5. The semiconductor device of claim 4, wherein the second active pattern includes a metal-semiconductor compound layer contacting the bit line.

6. The semiconductor device of claim 1, wherein the first active pattern includes a first source/drain region, a second source/drain region, and a channel region between the first source/drain region and the second source/drain region, and
the first source/drain region is in contact with the bit line.

7. The semiconductor device of claim 6, wherein the charge storage element overlaps the channel region in the vertical direction.

8. The semiconductor device of claim 6, wherein the charge storage element overlaps the second source/drain region in the vertical direction.

9. The semiconductor device of claim 1, wherein the charge storage element is disposed to be offset from the first gate electrode in the first horizontal direction.

10. The semiconductor device of claim 1, wherein the charge storage element partially overlaps the first gate electrode in the vertical direction.

11. The semiconductor device of claim 1, further including:
at least one upper work function controlling layer disposed at a same level as a level of the first gate electrode; and
at least one lower work function controlling layer disposed at a same level as a level of the second gate electrode,
wherein the at least one upper work function controlling layer and the at least one lower work function controlling layer include materials different from the first gate electrode and the second gate electrode.

12. The semiconductor device of claim 11, wherein the at least one upper work function controlling layer overlaps the first active pattern in the vertical direction, and
the at least one lower work function controlling layer overlaps the second active pattern in the vertical direction.

13. The semiconductor device of claim 1, further including a plate electrode spaced apart from the bit line in the first horizontal direction and contacting the first active pattern.

14. The semiconductor device of claim 13, wherein a portion of the first active pattern extends in the vertical direction and is in contact with the plate electrode.

15. A semiconductor device comprising:
bit lines extending on a substrate in a first horizontal direction and a vertical direction, wherein the bit lines are spaced apart from one another in a second horizontal direction, intersecting the first horizontal direction;
plate electrodes extending in the vertical direction and spaced apart from one another in the second horizontal direction, wherein the plate electrodes are spaced apart from the bit lines in the first horizontal direction;
channel structures disposed between the bit lines and the plate electrodes and extending in the first horizontal direction, wherein the channel structures are spaced apart from one another in the first horizontal direction and the vertical direction, with the bit lines interposed therebetween; and
first gate electrodes and second gate electrodes, spaced apart from one another in the vertical direction, with the channel structures interposed therebetween,
wherein the channel structures include:
first active patterns extending in the first horizontal direction and adjacent to the first gate electrodes;
second active patterns extending in the first horizontal direction and adjacent to the second gate electrodes; and
charge storage elements contacting the second active patterns and disposed between the plate electrodes and the second active patterns.

16. The semiconductor device of claim 15, further including a dielectric structure covering side surfaces of the plate electrodes and extending in the vertical direction,
wherein the dielectric structure covers the channel structures.

17. The semiconductor device of claim 16, wherein the dielectric structure includes dielectric material layers between the first active patterns and the charge storage elements and between the first active patterns and the second active patterns.

18. The semiconductor device of claim 16, wherein the dielectric structure includes gate dielectric layers between the first active patterns and the first gate electrodes and between the second active patterns and the second gate electrodes.

19. The semiconductor device of claim 15, wherein side surfaces of the plate electrodes include concave curved surfaces between the channel structures.

20. A semiconductor device comprising:
a first active pattern extending on a substrate in a first horizontal direction;
a first gate electrode at least partially overlapping the first active pattern in a vertical direction and adjacent to the first active pattern, wherein the first gate electrode extends in a second horizontal direction, intersecting the first horizontal direction;
a second active pattern extending in the first horizontal direction, wherein the second active pattern includes a first surface and a second surface, spaced apart from the first surface in the first horizontal direction;
a bit line contacting the first surface of the second active pattern and extending in the vertical direction;
a charge storage element contacting the second surface of the second active pattern;
a second gate electrode at least partially overlapping the second active pattern in the vertical direction and adjacent to the second active pattern, wherein the second gate electrode extends in the second horizontal direction;
a first gate capping layer and a second gate capping layer contacting the bit line and respectively contacting the first gate electrode and the second gate electrode; and
a plate electrode spaced apart from the bit line in the first horizontal direction and contacting the first active pattern,
wherein the first gate electrode and the second gate electrode are spaced apart from one another in the vertical direction, with the first active pattern and the second active pattern interposed therebetween, and
the second active pattern and the charge storage element overlap the first active pattern in the vertical direction.
